(19) United States
(12) Patent Application Publication
(10) Pub. No.: US 2017/0064854 A1
(43) Pub. Date: Mar. 2, 2017

(54) Mobile Device Cover With Strap

(71) Applicant: SKIP HOP, INC., New York, NY (US)

(72) Inventors: Adam L. HAYES, Brooklyn, NY (US); Janet VILLANO, Jersey City, NJ (US); Benjamin BEARSCH, Brooklyn, NY (US); Daulton KAO, Long Island City, NY (US); Ellen DIAMANT, New York, NY (US); Chelsea CARTER, Jersey City, NJ (US)

(21) Appl. No.: 14/833,923

(22) Filed: Aug. 24, 2015

(51) Int. Cl. H05K 5/03; H05K 5/00; A45F 5/00; A45C 11/00; A45C 13/10; H04B 1/3888; H05K 5/02

(52) U.S. Cl. CPC H05K 5/03; H04B 1/3888; H05K 5/0086; H05K 5/0017; H05K 5/023; A45C 11/00; A45C 13/10; A45F 5/00; A45C 2011/001; A45C 2011/002; A45C 2011/003; A45C 2013/1015

(57) ABSTRACT

A cover for a mobile electronic device includes a main body and a strap. The main body forms a pocket for receiving a mobile electronic device. A strap is attached to the main body on one end and has a post width head extending from a surface of the strap. The strap has at least one aperture formed therethrough having a sufficient size to permit the head to fit therethrough and removably lock the head in place thereby forming a loop.

### FIELD OF INVENTION

The present invention relates to a mobile device cover and in particular a device cover for a mobile electronic device in which the cover has an adjustable strap.

### BACKGROUND OF THE INVENTION

Mobile electronic devices have become increasingly popular for use as communication devices such as mobile telephones, email devices, and intern& devices and entertainment devices including personal music and video players such as Apple's iPod and platforms for playing games. The mobile devices include but are not limited to mobile phones/smartphones and tablet computers. In order to protect the electronic device, different covers have been designed depending on the electronic device and protection to be sought. For example, for use when exercising, one may select a case with an arm band strap for attaching the mobile device to ones arm. Typically straps for these cases have a loop and fabric fastener such as VELCRO®. The VELCRO® allows one to easily adjust and fasten the case with mobile electronic device to ones arm and then easily unfasten the strap for removing the device in the cover from ones arm.

With mobile devices becoming increasingly used for entertainment, software platform designers and developers have created devices and applications to run on electronic devices. Some have been designed specifically for infants and toddlers. Often, parents will allow their children to view content on the electronic device. Current electronic devices covers specifically designed to provide protection for electronic devices which adults are likely to give to young children and toddlers, include rugged cases which enclose the electronic device and provide protection should the electronic device be dropped to the ground.

### SUMMARY OF THE INVENTION

The present invention relates to a cover for a mobile electronic device in which the cover includes a main body forming a pocket for receiving a mobile electronic device and a strap attached to the main body. The strap in one advantageous form, is composed of an elastic material such as silicone. The strap has one or more slits or holes and a button or knob which fits through the holes or slits forming a loop. The button or knob is selectively removable from the holes or slits for allowing one to form the loop around a bar such as a stroller bar or frame of a stroller, shopping cart, etc. or other enclosure for attaching a strap with cover. The button or knob fits tightly in the slits of the strap allowing for a snug tight locking arrangement. As a result, the strap will remain attached to the bar to which it is connected and resists being removed until one purposely forces the slit or hole over the head of the button or knob.

The present invention, in one form thereof, relates to a cover for a mobile electronic device. The cover includes a main body having a closeable opening on one end. The main body forms a pocket for receiving a mobile electronic device inserted through the closeable opening. A strap is attached to the main body on one end and has a post with head extending from a surface of the strap. The strap has at least aperture formed therethrough having a sufficient size to permit the head to fit therethrough and removably locked in place, forming a loop. In one advantageous further embodiment, at least a portion of the strap surrounding the aperture is made of an elastic material. The aperture is smaller than the head, prior to insertion through the aperture to allow the strap to stretch thereby increasing the size of the aperture when the head is being pushed through the aperture. In one form, the aperture remains slightly larger when the post is disposed therethrough thereby providing a snug arrangement removably locking the head in place.

In one further alternative embodiment, the cover has a transparent material window which can be aligned with the display screen of a mobile device when disposed in the pocket. The transparent material allows one to use a touch screen of a mobile device through the transport material.

In yet a further alternative embodiment, the main body is composed of neoprene. Neoprene is a stretchable material allowing the cover to accommodate mobile devices having varying lengths, widths and thicknesses.

The present invention, in another form thereof, relates to a cover for a mobile electronic device. The cover includes a main body and a strap. The main body has a closeable opening on one end. The main body forms a pocket for receiving a mobile electronic device inserted through the closeable opening. The strap is attached to the main body on one end. The strap has a button attached to a post extending from a surface of the strap. The strap has at least one buttonhole adapted to permit a button to fit completely through the buttonhole and to be removably locked in place thereby forming a loop.

In one advantageous form, the buttonhole has a width smaller than that of the button when the button is not disposed in the buttonhole. In one further specific form, the buttonhole has a width less than the width of the post when the post is not disposed in the buttonhole and when the button with post is disposed in the buttonhole, the buttonhole is stretched, relative to its dimension when the post is not disposed therethrough, thereby tightly locking the button in place.

It will now be appreciated that the present cover provides features and advantages not found in prior mobile device covers. For example, unlike mobile device covers with VELCRO® straps, the present strap allows for a more secure connection eliminating the chance that the strap can become unfastened allowing the mobile device to be inadvertently dropped. In addition, due to the relative strength in which the strap forms a loop, the fastening arrangement is less likely to be unfastened by an infant or small child.

### BRIEF DESCRIPTION OF THE DRAWINGS

The present invention will now be described with regard to the drawings as follows.

FIG. 1 shows a mobile device in a cover with strap in accordance with the present invention.

FIG. 2 is the cover from FIG. 1 without mobile device viewed from the front in accordance with the present invention.

FIG. 3 shows the mobile cover of FIG. 2 viewed from the rear, in which the strap forms a loop for attachment to a bar or the like in accordance with the present.

FIG. 4 is the same cover of FIG. 3, shown from the front.

FIG. 5 is a top partial plan view of a buttonhole of the strap for the cover without button disposed therethrough, in accordance with the present invention.

FIG. 6 is a top partial plan view of the buttonhole of the strap in which a button is disposed, therethrough, in accordance with the present invention.

FIG. 7 is a top partial plan view of an alternative buttonhole of another strap in accordance with the present invention.

FIG. 8 is a top partial plan view of yet alternative buttonhole of another strap in accordance with the present invention.

FIG. 9 is an exploded view of the cover in accordance with the present invention.

FIG. 10 shows the mobile device in the cover attached to a stroller in accordance with the present invention.

FIG. 11A and FIG. 11B shows how the mobile device in the cover can be attached to a stroller/bar in an horizontal position in accordance with the present invention.

FIG. 12 is an alternative strap for the mobile device cover, in accordance with another aspect of the present invention.

FIG. 13 is another alternative strap for the mobile device, in accordance with another aspect of the present invention.

### DETAILED DESCRIPTION

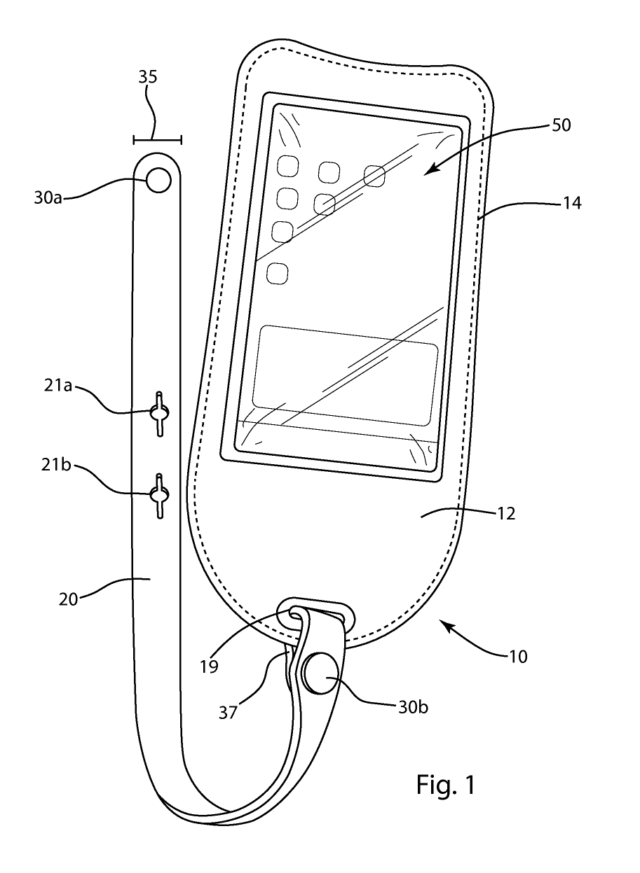

The present invention will now be described with regard to the Figures. FIG. 1 shows mobile cover 10 with strap 20. The mobile cover can be used for mobile devices which include but are not limited to a mobile or cellular telephone such as mobile phone 50. However, the cover 10 may be modified in shape to accommodate other mobile devices which include but are not limited to tablet computers, e-readers and the like.

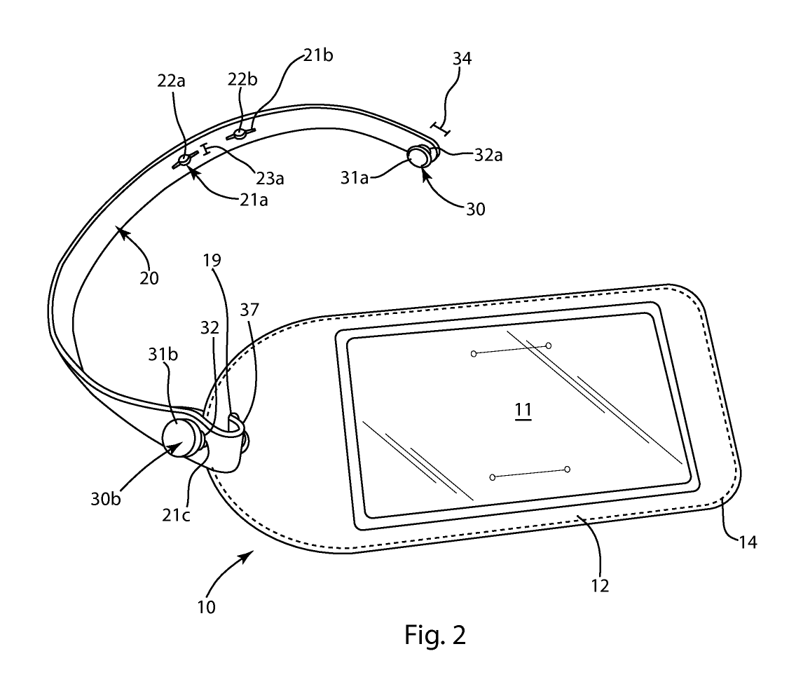

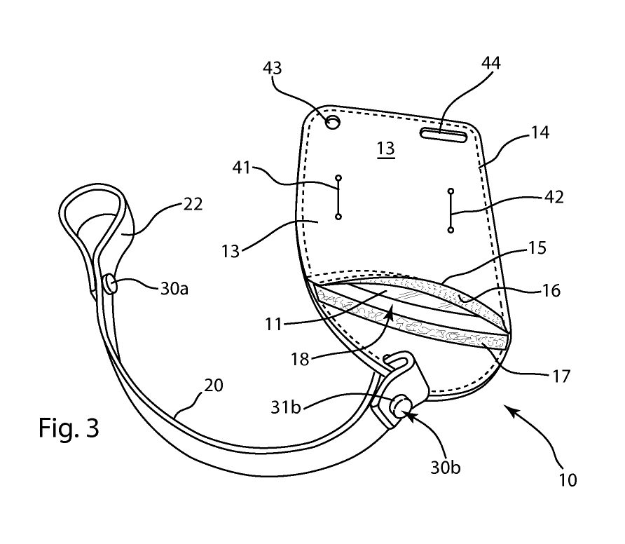

Referring now to FIG. 2 and FIG. 3, the cover 10 is composed of a front panel 12 and a rear panel 13 which are joined together by stitching 14 to form a main body of the cover 10. Alternatively, front panel 12 and rear panel 13 can be joined together using alternative means which include but are not limited to an adhesive such as hot glue or a single material folded over and stitched on one side as two possible none limiting examples. The cover 10 is composed of a soft material which includes but is not limited to neoprene. Neoprene or other suitable material is stretchable allowing the cover 10 to accommodate mobile devices having varying dimensions such as a length, width and thicknesses. Window 11 is formed of a suitable plastic material which allows one of operate a touchscreen of conventional mobile devices through the transparent material.

Stitching 14 is on three sides leaving a closeable opening 15 selectively closeable using a suitable fastener such as a loop and fabric fastener, shown in FIG. 3 as loop surface 16 and fabric surface 17. The front panel 12 and rear panel 13 closed on three sides with opening 15 define a pocket 18.

Pocket 18 accommodates the mobile device 50. Since the material of front panel 12 and rear panel 13 is stretchable, e.g. if composed of neoprene, the size of pocket 18 is adjustable by stretching to accommodate mobile devices having varying lengths, widths and thicknesses.

Referring specifically to FIG. 3, a pair of slits or cut openings 41, 42 are formed through rear panel 13 into pocket 18. A strap can be threaded through the two cut openings 41, 42 for use in an alternative strap attachment. Round opening 43 and oblong opening 44 are also formed through rear panel 13 into pocket 18. The round opening 43 and oblong opening 44 can align with a camera of electronic device 50 to allow taking photographs or for attaching a headphone plug to the electronic device 50.

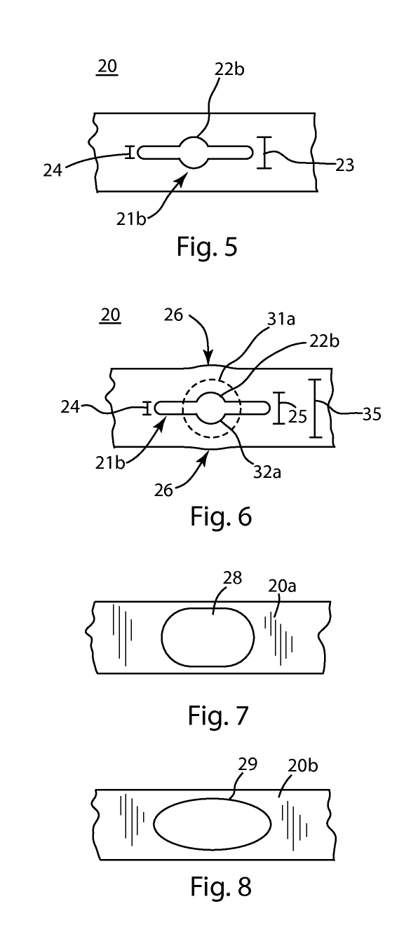

The strap 20 has a series of apertures or slots which form buttonholes (i.e. buttonholes 21a, 21b, 21c) and two buttons 30a, 31b on opposite ends of strap 20. The buttonholes 21a, 21b, 21c generally have a rectangular or rectilinear shape with a center bore 22a, 22b, 22c. The buttons 30a, 30b have a buttonhead 31a, 31b which is disposed upon a post 32a, 32b extending from a surface of the strap 20. Referring now to FIG. 2 and FIGS. 5-7, bore 22a, 22b when post 32a is not disposed therethrough has a diameter 23 (see FIG. 5) which is slightly smaller than diameter 34 of post 32a (see FIG. 2). When post 32a is disposed through bore 22a, 22b, the diameter increases to have diameter 25 shown in FIG. 6 (where the buttonhead 31a is drawn in broken lines to more easily illustrate post 32a and the enlarged bore 22b).

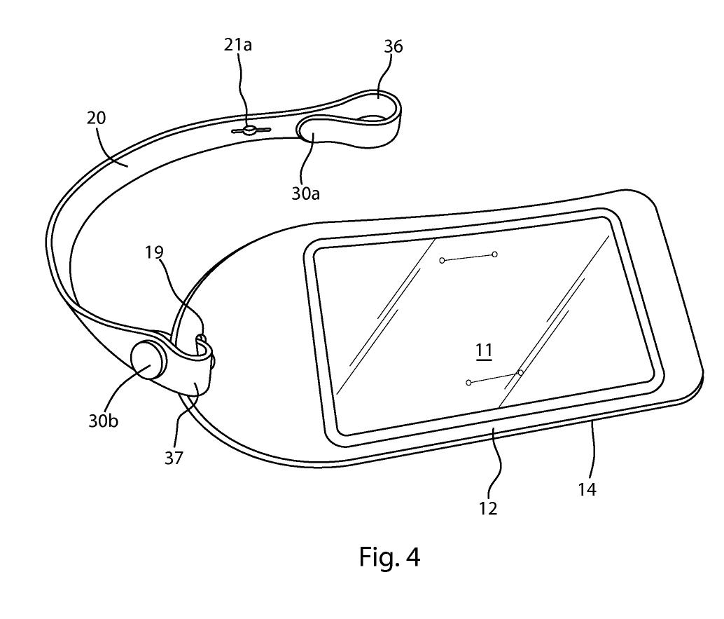

Advantageously, the strap 20 or at least a portion adjacent the buttonholes 21a, 21b, 21c is formed of an elastic material such as silicone. Area around the buttonholes 21a, 21b, 21c stretch as the button head 31a, 31b with post 32b is pushed through the buttonhole allowing the buttonhole 21a, 21b, 21c to be enlarged as the button head 31a, 31b passes through the hole. Since the bore 22a, 22b diameter 23 and slit width 24 (see e.g. FIG. 5) is less than the diameter 35 of the buttonhead 31a (FIGS. 2 and 6), the button 30a is held in a tight snug arrangement in buttonhole 21a, 21b to thereby securely form a loop 36 (see e.g. FIG. 3 and FIG. 4).

Referring to the button connection arrangement in more detail, as previously discussed, FIG. 5 is a plan view showing buttonhole 21b without post 32a of button 30a being disposed therethrough. FIG. 6 is a plan view of the buttonhole 21b with post 32a disposed therethrough, with the button head 31a drawn in broken lines to more easily see the post 32a and the bore 22b. When post 32a is disposed in bore 22b, the diameter of the bore 22a increases from diameter 23 (FIG. 5) to diameter 25 (FIG. 6). Diameter 25 (FIG. 6) is the same as the diameter of post diameter 32a, which is larger than bore diameter 23 (i.e. the diameter of bore 22a, when post 32 is not disposed therethrough, e.g. FIG. 5). As a result, button 31a with post 32a is held tightly and snuggly in buttonhole 21b, thus locking the button to the buttonhole 21 to form loop 36.

In addition when post 32a is disposed in buttonhole 21b, a portion of the strap 20 adjacent the buttonhole, e.g. area 26 bulges outward slightly. This tight connection of button 30a in buttonhole 21a, 21b is not easily disconnected by the hands of infants and small children. As a result, strap 20 looped around a structure such as the bar of a stroller or shopping cart will remain in place until purposely removed by another, e.g. an adult.

The buttonhole can have alternative shapes to the shape of buttonhole 21a, 21b of strap 20. For example, as shown in FIG. 7, strap 20a has a racetrack shape buttonhole 28 and in FIG. 8, strap 20b has an oval shape buttonhole 29. Corresponding shaped buttons of strap 20a,20b allow for a connection between the buttons and the buttonholes 28,29.

Referring back to FIGS. 1-6, and 9, the strap 20 may have a series of buttonholes 21a, 21b allowing the length of loop 36 to be adjusted based on a desired use. In addition, additional buttonholes may be included along the length of strap 20. The loop 36 can have a diameter between 1 cm and 7 cm, by varying the location of buttonholes 21a, 21b.

In a similar manner, loop 37 (FIG. 2) is formed by pushing button 30b through buttonhole 21c. Loop 37 extends through slot 19 of the main body 11 of the cover 10. Alternatively, the strap 20 can be permanently attached to the cover through slot 19 by a permanent loop in the strap rather than using a selectively removable fastener such as a button 30b and buttonhole 21c.

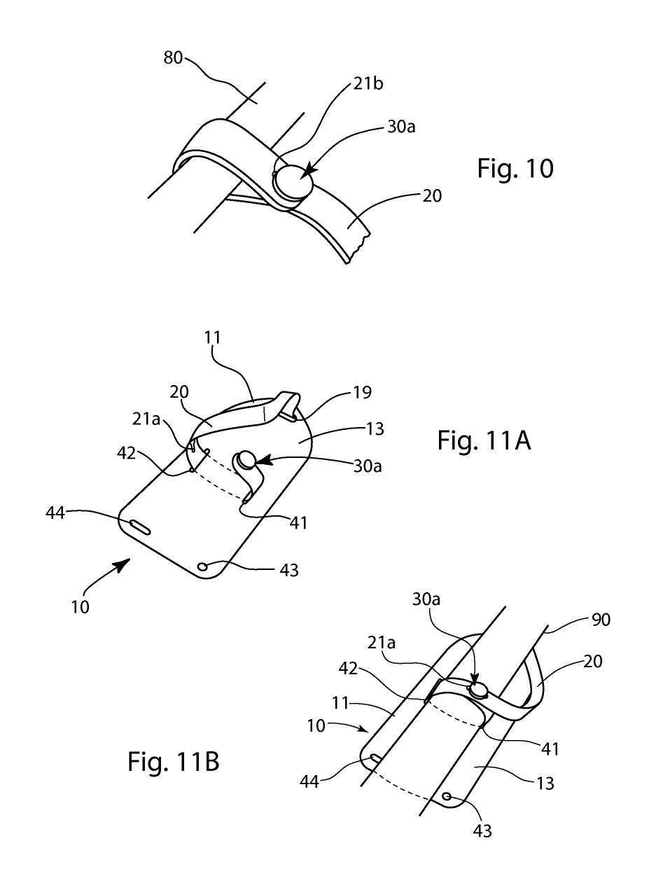

The strap 20 can be used to attach the mobile device in cover to a stroller bar or frame such as a shopping cart or alike. FIG. 10 shows the strap 20 attached to a stroller bar 80.

Referring to FIGS. 11A and 11B, in addition, the strap 20 can be used to mount the phone horizontally on a stroller bar 90. Strap 20 is looped through slot 19 of the main body 11 as discussed above and shown in FIGS. 1-4. Strap 20 is then thread through slit or cut out opening 42 into pocket 18 and opening 41 (FIG. 11A). The strap 20 is looped around stroller bar 90 and the buttonhead 31a is inserted through and locked in buttonhole 21a in the manner previously discussed.

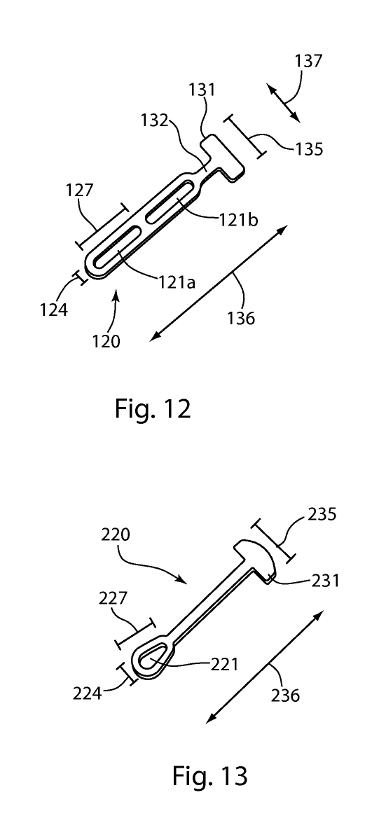

Referring generally to FIGS. 12 and 13, alternative straps 120,220 to strap 20 can be used with the present mobile device cover. Straps 120, 220, like strap 20, provide a secure connection between the main body 11 of the mobile cover and a structure to which the cover is attached, e.g. a stroller shopping cart bar.

Referring specifically to FIG. 12, strap 120 has two slots 121a, 121b, with a slot width 124 and length 127. Strap 120 can be composed of the same elastic material as strap 20. A post 132 extends from an end or surface of the strap, in a longitudinal axis direction 136 of the strap 120. Strap head 131 extends in a perpendicular direction 137 to the strap longitudinal axis 136. Head length 135 is less than slot length 127 but more than width 124, allowing head 131 to easily fit through slot 121a, 121b, when the strap 220 is twisted 90 degrees about the longitudinal axis 136.

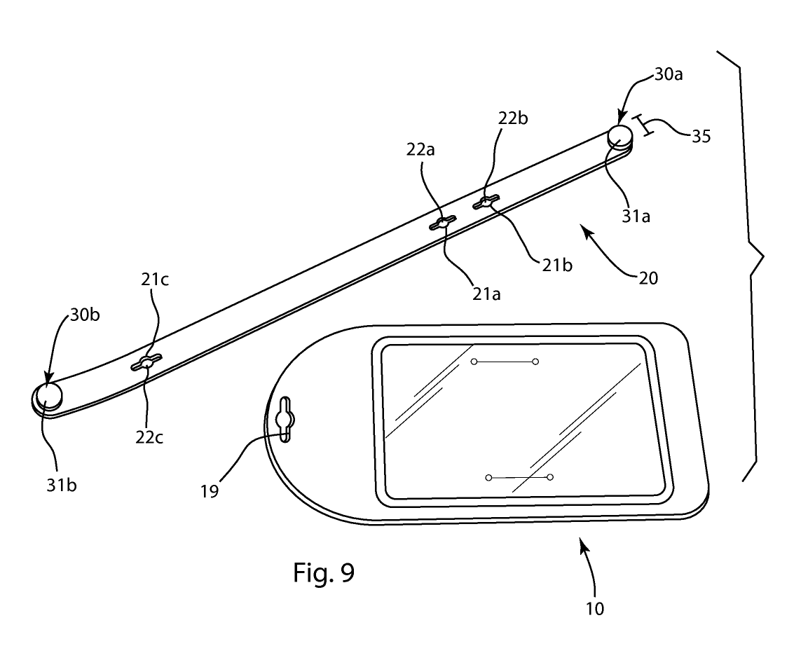

In use, the end of strap 120, opposite head is threaded through slot 19 (FIG. 9) or slits or cut out openings 41,42 (FIG. 3), looped around a bar or other structure, and head 131 is twisted 90 degrees about longitudinal axis 136 and inserted through hole 121a,121b, and then head 131 is twisted the opposite way to thereby lock the strap in place to the structure.

Referring now specifically to FIG. 13, strap 220 is composed of the same material as that of strap 20. Strap 220 has hole 221 with a slot length 227. Head 231 extends from an end or surface of the strap 220, opposite that of hole 221, in a perpendicular direction to strap longitudinal direction 236. The head length 135 is more than hole width 224 and slightly wider than hole length 227 [INVENTORS: PLEASE CONFIRM DIMENSIONS STATED HERE] Due to the elasticity of strap 220, one can twist strap 220, about longitudinal axis 236, and insert head 231 through hole 221, allowing strap 220 to stretch as head 231 is pushed through. Twisting the head 231 in the opposite direction, locks the head 231 in place.

Attachment of a mobile device cover using strap 220 is essentially the same as discussed above with regard to strap 120. The slot 221 end is threaded through slot 19 (FIG. 9) or slits/cut out openings 41,42 (FIG. 3), looped around a bar or other structure, and head 231 is twisted 90 degrees about longitudinal axis 236 and inserted through hole 121, and then head 231 is twisted the opposite way to thereby lock the strap in place to the structure.

It will now be apparent that the present cover with strap has advantages and features not found in prior covers. The present cover allows one to securely attach the strap to a bar or other suitable device in a manner more secure than conventional Velcro strap covers known in the art. The snug tight fit of the buttons through the slots or buttonholes in the strap allow an adult to easily attach the strap to a bar of a stroller or a shopping cart but is sufficiently tight to limit an infant or child from inadvertently removing the strap. As a result, the present cover reduces the chance that a mobile device disposed in the cover will accidently be dropped onto the ground.

One of ordinary skill in the art will recognize that additional embodiments are also possible without departing from the teachings of the presently-disclosed subject matter. This detailed description, and particularly the specific details of the exemplary embodiments disclosed herein, is given primarily for clarity of understanding, and no unnecessary limitations are to be understood therefrom, for modifications will become apparent to those skilled in the art upon reading this disclosure and can be made without departing from the spirit and scope of the presently-disclosed subject matter.

What is claimed is:

1. A cover for a mobile electronic device, said cover comprising:
a main body having a closeable opening on one end, the main body forming a pocket for receiving a mobile electronic device insert through the closeable opening, and
a strap attached to the main body one end and having a post with head extending from a surface of the strap, the strap having at least one aperture, formed therethrough having a sufficient size to permit the head to fit therethrough and removeably lock in place, forming a loop.

2. The cover of claim 1, wherein at least a portion of the strap surrounding the aperture is made of an elastic material and the aperture is sufficiently small and head sufficiently large to allow the strap to stretch around the aperture, thereby increasing the size of the aperture when the head is being pushed through the aperture.

3. The cover of claim 2, wherein the aperture has a larger diameter when the post is disposed therethrough as compared to when the post is not disposed therethrough, thereby removeably locking the head in place.

4. The cover of claim 1, wherein the main body closeable opening is closed via a loop and hook fastener.

5. The cover of claim 1, wherein the aperture is a slit having a substantially rectangular shape with a center circular portion with a diameter less than that of the post, when the post is not disposed in the aperture.

6. The cover of claim 5, wherein the slit has a relative longer length dimension and relative shorter width dimension and the circular portion diameter is greater than a width of the slit.

7. The cover of claim 1, wherein the strap has at least two apertures for adjusting a length of the loop based on which of the two apertures the head is disposed.

8. The cover of claim 1, wherein the strap is attached to the mobile device via another post with head extending from a surface of the strap, and a second aperture proximate the another post, and the cover has a slot for receiving the head, wherein the strap is removeable attached to the main body via the head fitting through the slot of the main body and forming a loop by being inserted through the second aperture, releaseably locking the head to the strap.

9. The cover of claim 1, further comprising a transparent material alignable with a display screen of a mobile device when disposed in the pocket.

10. The cover of claim 9, wherein the transparent material permits use of a touch screen display of the mobile device when disposed in the pocket.

11. The cover of claim 1, wherein the main body is composed of neoprene.

12. A cover for a mobile electronic device, said cover comprising:
a main body having a closeable opening on one end, the main body forming a pocket for receiving a mobile electronic device insert through the closeable opening, and
a strap attached to the main body one end, the strap having a button attached to a post extending from a surface of the strap, the strap having at least one button hole adapted to permit the button to fit completely therethrough, and removeably locking in place, thereby forming a loop.

13. The cover of claim 12, wherein the button hole has a width smaller than that of the button when the button is not disposed in the button hole.

14. The cover of claim 13, wherein the button hole has a width less than a width of the post when the post in not disposed in the button hole and when the button with post is disposed in the button hole, the hole is stretched, relative to its dimension when not disposed therethrough, thereby tightly locking the button in place.

15. The cover of claim 12, wherein the button hole is a slit having a substantially rectangular shape with a center circular portion with a diameter less than that of the post, when the post is not disposed in the button hole.

16. The cover of claim 15, wherein the slit has a relative longer length dimension and relative shorter width dimension and the circular portion diameter is greater than a width of the slit.

17. The cover of claim 12, further comprising a transparent material alignable with a display screen of a mobile device when disposed in the pocket.

18. The cover of claim 17, wherein the transparent material permits use of a touch screen display of the mobile device when disposed in the pocket.

19. The cover of claim 12, wherein the main body is composed of neoprene.

20. A cover for a mobile electronic device, said cover comprising:
a main body having a closeable opening on one end, the main body forming a pocket for receiving a mobile electronic device insert through the closeable opening, and
a strap attachable to the main body, the strap having a longitudinal axis and a head at one end, extending in a direction perpendicular to the longitudinal axis, said strap having a least one aperture therethrough having a sufficient size to permit the head to fit therethrough and removeably lock in place, forming a loop.

21. The cover of claim 20, wherein said main body has a slot through which said strap is disposed.

22. The cover of claim 20, wherein at least a portion of the strap surrounding the aperture is made of an elastic material and the aperture is sufficiently small and head sufficiently large to allow the strap to stretch around the aperture, thereby increasing the size of the aperture when the head is being pushed through the aperture.

23. The cover of claim 20, wherein the head extends in two directions perpendicular to the longitudinal axis of the strap.
